(19) United States
(12) Patent Application Publication
(10) Pub. No.: US 2026/0304991 A1
(43) Pub. Date: Oct. 1, 2026

(54) DETECTION APPARATUS AND DRIVING METHOD THEREFOR

(71) Applicants: Beijing BOE Optoelectronics Technology Co., Ltd., Beijing (CN); BOE Technology Group Co., Ltd., Beijing (CN); Beijing BOE Technology Development Co., Ltd., Beijing (CN)

(72) Inventors: Wenjie ZHONG, Beijing (CN); Bo FU, Beijng (CN); Xiantao LIU, Beijng (CN); Chen MENG, Beijing (CN); Yonghui WANG, Beijing (CN); Haibo YU, Beijing (CN)

(21) Appl. No.: 19/479,560

(22) PCT Filed: Sep. 27, 2023
(86) PCT No.: PCT/CN2023/122132

§ 371 Date: Oct. 28, 2025

(51) Int. Cl. H10F 39/00; H10F 39/18; H10F 39/95

(52) U.S. Cl. CPC H10F 39/809; H10F 39/1895; H10F 39/811; H10F 39/95

(57) ABSTRACT

A detection apparatus includes: a detection substrate including a detection surface, a back surface arranged opposite one another, first to third edges connecting the detection surface and the back surface, the first side edge being arranged opposite to the second side edge, the third side edge being connected to the first, second side edges; a driving system including first circuit boards extending, by passing over at least one of the first, second side edges, from back surface side to back surface side, second circuit boards extending, by passing over the third side edge, from detection surface side to back surface side; on back surface side, the farthest distance between the first circuit board and the back surface being unequal to the farthest distance between the second circuit board and the back surface in the first direction, the first direction being perpendicular to the detection surface.

### CROSS-REFERENCE TO RELATED APPLICATION

This application is a National Stage of International Application No. PCT/CN2023/122132, filed Sep. 27, 2023, of which is hereby incorporated by reference in its entirety.

### TECHNICAL FIELD

The present disclosure relates to the field of photoelectric detection technology, and in particular to a detection apparatus and a driving method therefor.

### BACKGROUND

X-ray detection technology is widely used in industrial non-destructive testing, container scanning, circuit board inspection, medical, security, industry and other fields, and has broad application prospects. Traditional X-ray imaging technology belongs to analog signal imaging, with low resolution and poor image quality. The X-ray digital imaging technology (Digital Radio Graphy, DR) that appeared in the late 1990s uses an X-ray detection substrate to directly convert X-ray images into digital images. It has become the leading direction of digital X-ray photography technology with its significant advantages such as convenient operation, fast imaging speed, high imaging resolution, clear converted digital images, and easy storage and transmission of digital images.

### SUMMARY

Some embodiments of the present disclosure provide a detection apparatus and a driving method therefor, including: a detection substrate including:
a detection surface and a back surface arranged opposite to each other, and
a first side edge, a second side edge, and a third side edge each connects the detection surface and the back surface,
the first side edge is arranged opposite to the second side edge, and the third side edge connects the first side edge and the second side edge; and
a driving system including:
a plurality of first circuit boards, wherein the plurality of first circuit boards extend from a side where the detection surface is arranged to a side where the back surface is arranged, through at least one of the first side edge and the second side edge; a farthest distance between the first circuit boards on the side where the back surface is arranged and the back surface, in a first direction is a first distance, and the first direction is a direction perpendicular to the detection surface;
a plurality of second circuit boards, wherein the plurality of second circuit boards extend from the side where the detection surface is arranged to the side where the back surface is arranged through the third side edge; a farthest distance between the second circuit boards on the side where the back surface is arranged and the back surface, in the first direction is a second distance, and the second distance is unequal to the first distance.

In some embodiments of the detection apparatus, the first circuit board includes a reading chip, the second circuit board includes a gate driving chip, and the second distance is greater than the first distance.

In some embodiments of the detection apparatus, the detection apparatus further includes a middle frame, wherein the middle frame includes a bottom frame and a side frame, the bottom frame is arranged on a side of the back surface facing away from the detection surface, the side frame is fixed to an end of the bottom frame adjacent to the third side edge, and the side frame is arranged on a side of the bottom frame facing away from the back surface;
the first circuit boards extends to the side of the bottom frame facing away from the back surface, and the second circuit boards extend to a surface of the side frame facing away from the back surface.

In some embodiments of the detection apparatus, the reading chip is arranged on the side of the bottom frame facing away from the back surface, and the gate driving chip is arranged on a side surface of the side frame arranged on a side where the third side edge is arranged.

In some embodiments of the detection apparatus, the plurality of first circuit boards include a plurality of first sub-circuit boards and a plurality of second sub-circuit boards, wherein the plurality of first sub-circuit boards extend from the side where the detection surface is arranged to the side of the bottom frame facing away from the back surface through the first side edge, and the plurality of second sub-circuit boards extend from the side where the detection surface is arranged to the side of the bottom frame facing away from the back surface through the second side edge; and an arrangement position of the plurality of first sub-circuit boards and an arrangement position of the plurality of second sub-circuit boards are symmetrical about a second direction, and the second direction is a direction perpendicular to the third side edge.

In some embodiments of the detection apparatus, the driving system further includes two reading circuit boards arranged on the side of the bottom frame facing away from the back surface, wherein one of the two reading circuit boards is connected to the plurality of first sub-circuit boards, and the other one of the two reading circuit boards is connected to the plurality of second sub-circuit boards, and component structures of the two reading circuit boards are symmetrically arranged about a center of the detection substrate.

In some embodiments of the detection apparatus, the reading circuit board includes at least one first through hole, the reading circuit board is fixedly connected to the bottom frame at the at least one first through hole, and the at least one first through hole is a conductive hole.

In some embodiments of the detection apparatus, the reading circuit board further includes a first edge region arranged on a side of the at least one first through hole facing away from the center of the detection substrate, and a surface of the reading circuit board in contact with the bottom frame is conductively arranged in the first edge region.

In some embodiments of the detection apparatus, the reading circuit board further includes at least one first electrostatic protection circuit, the at least one first electrostatic protection circuit is arranged on a side of a first connection port close to the center of the detection substrate, and the first connection port connects the first circuit board with the reading circuit board.

In some embodiments of the detection apparatus, the reading circuit board further includes at least one first filtering circuit, and the at least one first filtering circuit is arranged on a side of the at least one first electrostatic protection circuit close to the center of the detection substrate.

In some embodiments of the detection apparatus, the driving system further includes a gate drive circuit board and a main control board, wherein the gate drive circuit board is connected to the second circuit board, and the main control board is arranged between a layer where the reading circuit board is arranged and a layer where the gate drive circuit board is arranged.

In some embodiments of the detection apparatus, the reading circuit board includes a first boundary facing away from the center of the detection substrate and extending along the second direction, and the main control board includes a second boundary facing away from the center of the detection substrate and extending along the second direction, wherein the first boundary is arranged on a side of the second boundary facing away from the center of the detection substrate, and a third distance is provided between the first boundary and the second boundary, the second direction is a direction perpendicular to the third side edge, and a third direction is a direction perpendicular to the first side edge.

In some embodiments of the detection apparatus, the driving system further includes a first flat flexible cable, the reading circuit board further includes a first power signal connector, the main control board includes a second power signal connector, and the first power signal connector is connected to the second power signal connector through the first flat flexible cable.

In some embodiments of the detection apparatus, the driving system further includes a first flexible circuit board, the reading circuit board further includes a first data signal connector, the main control board includes a plurality of second data signal connectors, the first data signal connector is connected to at least one of the second data signal connectors through the first flexible circuit board, and a quantity of the second data signal connectors is greater than a quantity of the first data signal connector or a quantity of the first flexible circuit board.

In some embodiments of the detection apparatus, the second data signal connector is a small video connector, the small video connector includes a shielding layer, and the shielding layer is grounded.

In some embodiments of the detection apparatus, the first flexible circuit board includes a plurality of pins arranged side by side, and a plurality of differential design cables, wherein an outermost pin of the plurality of pins are grounded, and remaining pins of the plurality of pins are connected to the differential design cables.

In some embodiments of the detection apparatus, the reading circuit board further includes at least one second through hole, the main control board includes at least one third through hole arranged to be conductively connected to the at least one second through hole, the main control board is fixedly connected to the bottom frame at the at least one third through hole, and the at least one third through hole is a conductive hole.

In some embodiments of the detection apparatus, the detection apparatus further includes a heat-conducting structure, wherein the heat-conducting structure is arranged between the first circuit board and the bottom frame and is arranged in contact with the reading chip and a surface of the bottom frame facing away from the back surface.

In some embodiments of the detection apparatus, the driving system further includes a gate drive circuit board, and the gate drive circuit board is connected to the second circuit board; the gate drive circuit board includes at least one fourth through hole, and the gate drive circuit board is fixedly connected to the side frame at the at least one fourth through hole, and the at least one fourth through hole is a conductive hole.

In some embodiments of the detection apparatus, the gate drive circuit board further includes a second edge region covering the at least one fourth through hole, and a surface of the gate drive circuit board in contact with the side frame is conductively arranged in the second edge region.

In some embodiments of the detection apparatus, the gate drive circuit board further includes at least one second electrostatic protection circuit, and the at least one second electrostatic protection circuit is arranged on a side of a second connection port close to the center of the detection substrate, and the second connection port connects the second circuit board with the gate drive circuit board.

In some embodiments of the detection apparatus, the gate drive circuit board further includes at least one second filter circuit, and the at least one second filter circuit is arranged on a side of the at least one second electrostatic protection circuit close to the center of the detection substrate.

In some embodiments of the detection apparatus, the middle frame further includes a boss structure, the boss structure is fixed to the side of the bottom frame facing away from the back surface, and the boss structure is fixedly connected to a part of a surface of the side frame close to the bottom frame;
the gate drive circuit board further includes at least one fifth through hole, the gate drive circuit board is fixedly connected to the boss structure at the at least one fifth through hole, and the at least one fifth through hole is a conductive hole.

In some embodiments of the detection apparatus, the driving system further includes a main control board arranged on a side of the gate drive circuit board facing the bottom frame, the main control board includes a first notch structure, and the boss structure is accommodated in the first notch structure.

In some embodiments of the detection apparatus, the driving system further includes a second flat flexible cable, the gate drive circuit board further includes a third power signal connector, the main control board includes a fourth power signal connector, and the third power signal connector is connected to the fourth power signal connector through the second flat flexible cable.

In some embodiments of the detection apparatus, the driving system further includes a second flexible circuit board, the gate circuit board further includes a first scan signal connector, the main control board includes a second scan signal connector, and the first scan signal connector is connected to the second scan signal connector through the second flexible circuit board.

In some embodiments of the detection apparatus, the main control board further includes a second notch structure, and the second notch structure is arranged opposite to the first notch structure;
the detection apparatus further includes a first adapter board, a part of the first adapter board is embedded in the second notch structure, and the first adapter board is connected to the main control board.

In some embodiments of the detection apparatus, the driving system further includes an indicator light board and a power input board, and the indicator light board, the power input board and the first adapter board are arranged on a same vertical plane of the detection surface.

In some embodiments of the detection apparatus, the driving system further includes a main control board and a second adapter board, wherein the second adapter board includes a reading circuit board connected to the first circuit board, and a plurality types of signal expansion boards connected to the reading circuit board, and the main control board is connected to the reading circuit board through the signal expansion board.

In some embodiments of the detection apparatus, the driving system further includes a main control board, a second adapter board and a gold finger contact connector, wherein the second adapter board includes a reading circuit board connected to the first circuit board, and a gate drive circuit board connected to the second circuit board, and the main control board is connected to the reading circuit board and the gate drive circuit board through the gold finger contact connector.

On the other hand, some embodiments of the present disclosure provide a driving method of the detection apparatus, the detection substrate includes a plurality of data lines arranged in sequence, the plurality of first circuit boards include at least one first sub-circuit board connected to odd-numbered data lines at one end of the data lines, and at least one second sub-circuit board connected to even-numbered data lines at the other end of the data lines, the at least one first sub-circuit board and the at least one second sub-circuit board are symmetrically arranged about a center of the detection substrate;
the driving method includes:
obtaining and caching a plurality of first data signals output in positive sequence by the at least one first sub-circuit board and a plurality of second data signals outputted in positive sequence by the at least one second sub-circuit board;
flipping the plurality of second data signals output in positive sequence by the second sub-circuit board, to align the plurality of second data signals outputted by the second sub-circuit board in reverse sequence; and
framing and transmitting the plurality of first data signals output in positive sequence and the plurality of second data signals aligned in reverse sequence to a host computer.

### BRIEF DESCRIPTION OF FIGURES

FIG. 1 is a schematic diagram of the interference between a first chip-on-film and a second chip-on-film in the related art;

FIG. 2 is a schematic diagram of a first circuit board and a second circuit board provided by an embodiment of the present disclosure that do not interfere with each other;

FIG. 3 is a schematic diagram of a symmetrical design of a reading circuit board provided in an embodiment of the present disclosure;

FIG. 4 is a schematic diagram of the position of a second circuit board provided in an embodiment of the present disclosure;

FIG. 5 is a schematic diagram of another symmetrical design of a reading circuit board provided in an embodiment of the present disclosure;

FIG. 6 is a schematic diagram of another symmetrical design of a reading circuit board provided in an embodiment of the present disclosure;

FIG. 7 is a schematic diagram of a structure of a reading circuit board provided in an embodiment of the present disclosure;

FIG. 8 is another structural schematic diagram of a reading circuit board provided in an embodiment of the present disclosure;

FIG. 9 is a schematic diagram of a structure of a driving system provided in an embodiment of the present disclosure;

FIG. 10 is a schematic diagram of another structure of a driving system provided in an embodiment of the present disclosure;

FIG. 11 is a schematic diagram of the structure of a main control chip provided in an embodiment of the present disclosure;

FIG. 12 is a schematic diagram of a structure of a gate drive circuit board provided in an embodiment of the present disclosure;

FIG. 13 is a schematic diagram of another structure of the gate drive circuit board provided in an embodiment of the present disclosure;

FIG. 14 is a schematic diagram of another structure of a driving system provided in an embodiment of the present disclosure;

FIG. 15 is a schematic diagram of another structure of a driving system provided in an embodiment of the present disclosure;

FIG. 16 is a schematic diagram of another structure of a driving system provided in an embodiment of the present disclosure;

FIG. 17 is a schematic diagram of another structure of a driving system provided in an embodiment of the present disclosure;

FIG. 18 is a schematic diagram of another structure of a driving system provided in an embodiment of the present disclosure;

FIG. 19 is a schematic diagram of another structure of a driving system provided in an embodiment of the present disclosure;

FIG. 20 is a schematic diagram of another structure of a driving system provided in an embodiment of the present disclosure;

FIG. 21 is a schematic diagram of another structure of a driving system provided in an embodiment of the present disclosure;

FIG. 22 is a schematic diagram of the arrangement of the first sub-circuit board and the second sub-circuit board provided in an embodiment of the present disclosure;

FIG. 23 is a flow chart of a driving method provided by an embodiment of the present disclosure;

Numerals: 100—detection substrate; 101—first circuit board; 102—second circuit board; 103—middle frame; 1031—bottom frame; 1032—side frame; 1033—boss structure; 104—heat-conducting structure; 105—reading circuit board; 1051—first reading circuit board; 1052—second reading circuit board; 501—first electrostatic protection circuit; 502—first filtering circuit; 503—first power signal connector; 504—first data signal connector; 106—first protective layer; 107—main control board; 1071—second power signal connector; 1072—second data signal connector; 1073—FPGA main control; 1074—DDR3 cache; 1075—FLASH storage; 1076—system power supply; 1077—fourth power signal connector; 1078—second scan signal connector; 108—gate drive circuit board; 1081—second electrostatic protection circuit; 1082—second filtering circuit; 1083—third power signal connector; 1084—first scan signal connector; 109—first flat flexible cable; 110—first flexible circuit board; 111—fixing column; 112—second protective layer; 113—second flexible circuit board; 114—first adapter board; 115—third flexible circuit board; 116—indicator light board; 117—power input board; 118—fourth flexible circuit board; 119—fifth flexible circuit board; 120—second adapter board; 121—gold finger contact connector; S1—detection surface; S2—back surface; S3—first side edge; S4—second side edge; S5—third side edge ; S6—fourth side edge; d1—first distance; d2—second distance; d3—third distance; ROIC_L—first sub-circuit board; ROIC_R—second sub-circuit board; h1—first through hole; h2—second through hole; h3—third through hole; h4—fourth through hole; h5—fifth through hole; O—center of detection substrate; A1—first edge region; A2—second edge region; C1—first connection port; C2—second connection port; L1—first boundary; L2—second boundary.

### DETAILED DESCRIPTION

In order to make the purpose, technical solution and advantages of the embodiments of the present disclosure clearer, the technical solution of the embodiments of the present disclosure will be clearly and completely described in conjunction with the drawings of the embodiments of the present disclosure. It should be noted that in the drawings, the thickness of the layers, films, panels, regions, etc. is magnified for clarity. In the present disclosure, exemplary embodiments are described with reference to cross-sectional views of schematic diagrams of idealized embodiments. In this way, deviations from the shapes of the figures as a result of, for example, manufacturing technology and/or tolerances will be expected. Therefore, the embodiments described in the present disclosure should not be interpreted as being limited to the specific shapes of the regions shown in the present disclosure, but include deviations in shape caused by, for example, manufacturing. For example, an area illustrated or described as flat may typically have rough and/or nonlinear features; the illustrated sharp corners may be rounded, etc. Therefore, the areas shown in the figures are schematic in nature, and their sizes and shapes are not intended to illustrate the precise shapes of the regions, do not reflect the true proportions, and are intended only to illustrate the contents of the present disclosure. Moreover, the same or similar reference numerals throughout represent the same or similar elements or elements having the same or similar functions. In order to keep the following description of the embodiments of the present disclosure clear and concise, the present disclosure omits detailed descriptions of well-known functions and well-known components.

Unless otherwise defined, the technical terms or scientific terms used herein shall have the usual meanings understood by persons of ordinary skill in the field to which the present disclosure belongs. The words “first”, “second” and similar words used in the present disclosure specification and claims do not indicate any order, quantity or importance, but are only used to distinguish different components. Words such as “include” or “comprise” and the like mean that the elements or objects appearing before the word include the elements or objects listed after the word and their equivalents, without excluding other elements or objects. Words such as “connect” or “connected” and the like are not limited to physical or mechanical connections, but may include electrical connections, whether direct or indirect. “Inside”, “outside”, “upper”, “lower”, etc. are only used to indicate relative positional relationships. When the absolute position of the described object changes, the relative positional relationship may also change accordingly.

In the following description, when an element or layer is referred to as being “on” or “connected to” another element or layer, the element or layer may be directly on, directly connected to, or there may be an intermediate element or intermediate layer. When an element or layer is referred to as being “disposed on one side of” another element or layer, the element or layer may be directly on one side of, directly connected to, or there may be an intermediate element or intermediate layer. However, when an element or layer is referred to as being “directly on” or “directly connected to” another element or layer, there are no intermediate elements or intermediate layers. The term “and/or” includes any and all combinations of one or more of the associated listed items.

The x-ray detection substrate includes multiple gate lines and multiple data lines arranged in different layers, and detection pixels arranged in the regions defined by the multiple gate lines and multiple data lines. The gate lines intersect with the data lines. The detection pixels include thin film transistors and photodiodes with photosensitive characteristics. The gate lines control the conduction and cutoff of the thin film transistors, and the data lines cooperate with the gate lines to complete the transfer of the photocharge stored in the photodiode to generate electrical signals. The electrical signals are converted into digital signals through A/D conversion, and a computer then performs an image processing on the digital signals to form x-ray digital images.

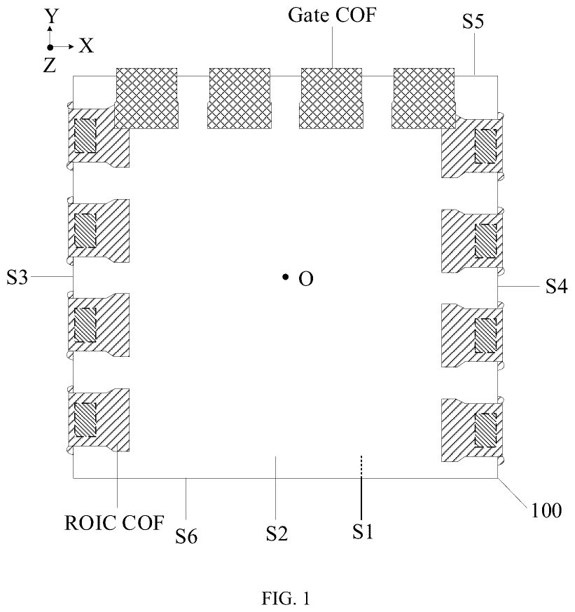

In some embodiments, as shown in FIG. 1, an x-ray detection substrate 100 in the related art includes a detection surface S1 and a back surface S2 disposed opposite to each other, a first side edge S3, a second side edge S4, and a third side edge S5. The first side edge S3, the second side edge S4 and the third side edge S5 connect the detection surface S1 and the back surface S2. The first side edge S3 and the second side edge S4 are disposed opposite to each other, and the third side edge S5 connects the first side edge S3 and the second side edge S4. The driving circuit of the x-ray detection substrate may include a plurality of first chip-on-film ROIC COFs having a reading chip, and a plurality of second chip-on-film Gate COFs having a gate driving chip. The first chip-on-film ROIC COF is connected to the data line on the side where the detection surface S1 is arranged, and the second chip-on-film Gate COF is connected to the gate line on the side where the detection surface S1 is arranged. In order to reduce the volume of the x-ray detection substrate, in FIG. 1, multiple first chip-on-films ROIC COF are flipped to the back surface S2 of the x-ray detection substrate via the first side edge S3 and the second side edge S4, and multiple second chip-on-films Gate COF are flipped to the back surface S2 of the x-ray detection substrate via the third side edge S5. However, since the multiple first chip-on-films ROIC COF and the multiple second chip-on-films Gate COF are at the same height after flipping, the first chip-on-films ROIC COF and the second chip-on-films Gate COF will interfere with each other at the corners of the first side edge S3 and the third side edge S5, and at the corners of the second side edge S4 and the third side edge S5.

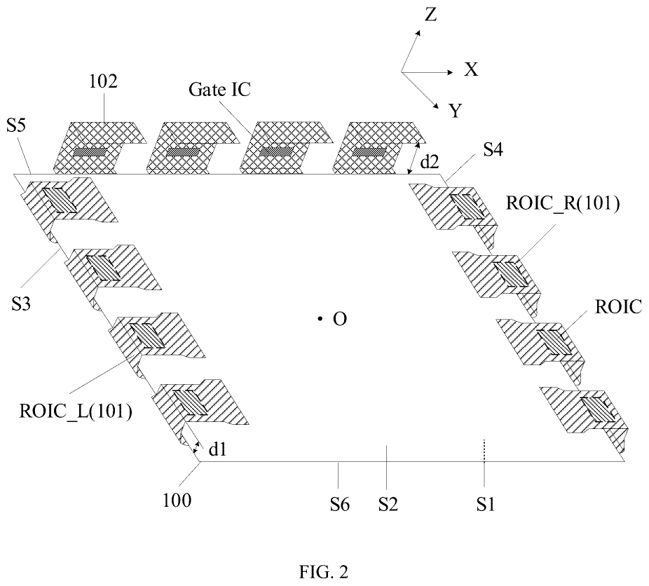

In order to at least solve the above technical problems existing in the related art, the present disclosure provides a detection apparatus, as shown in FIG. 2, which may include:
a detection substrate 100 including a detection surface S1 and a back surface S2 which are opposite to each other, a first side edge S3, a second side edge S4, and a third side edge S5 which connect the detection surface S1 and the back surface S2, the first side edge S3 and the second side edge S4 are opposite to each other, and the third side edge S5 connects the first side edge S3 and the second side edge S4;
a driving system including a plurality of first circuit boards 101, the plurality of first circuit boards 101 extend from a side where a detection surface S1 is arranged through at least one of a first side edge S3 and a second side edge S4 to a side where a back surface S2 is arranged; on the side where the back surface S2 is arranged, the maximum distance between the first circuit board 101 and the back surface S2 in a first direction Z is a first distance d1, and the first direction Z is a direction perpendicular to the detection surface S1;
a plurality of second circuit boards 102 extend from the side where the detection surface S1 is arranged through the third side edge S5 to the side where the back surface S2 is arranged; on the side where the back surface S2 is arranged, the maximum distance between the second circuit board 102 and the back surface S2 in the first direction Z is a second distance d2, and the second distance d2 is different from the first distance d1.

In the above-mentioned detection apparatus provided in the embodiment of the present disclosure, by setting the first circuit board 101 to have a first distance d1 with the back surface S2 after being flipped to the side where the back surface S2 is arranged, and the second circuit board 102 to have a second distance d2 with the back surface S2 after being flipped to the side where the back surface S2 is arranged, and the first distance d1 is different from the second distance d2, the flipping heights of the first circuit board 101 and the second circuit board 102 are staggered, thereby avoiding mutual interference between the first circuit board 101 and the second circuit board 102.

In some embodiments, in the above-mentioned detection apparatus provided by the embodiment of the present disclosure, as shown in FIG. 2, the first circuit board 101 includes a reading chip (ROIC). The second circuit board 102 includes a gate driver chip (Gate IC). The second distance d2 can be greater than the first distance d1, so that the reading chip (ROIC) can be flipped to the side where the back surface S2 is arranged for protection, so as to avoid the reading chip (ROIC) such as a precision semiconductor device being affected by radiation in the application scenario with relatively high x-ray metrology (such as industrial flaw detection). The gate driver chip (Gate IC) generates little heat, and the gate driver chip (Gate IC) is small, the operating voltage is high, and it is not easily affected by radiation. Therefore, even if the gate driver chip (Gate IC) is not flipped to the side where the back surface S2 is arranged for protection, it will not affect the normal operation of the gate driver chip (Gate IC). It should be understood that in the application scenario with low x-ray dose (such as finding lesions), the radiation interference to the reading chip (ROIC) is small. At this time, the first distance d1 can be set to be greater than the second distance d2, and the second distance d2 can be set to be greater than the first distance d1. As long as the two are different in size, mutual interference after flipping can be avoided. Optionally, the first circuit board 101 and the second circuit board 102 may both be chip-on-film (COF).

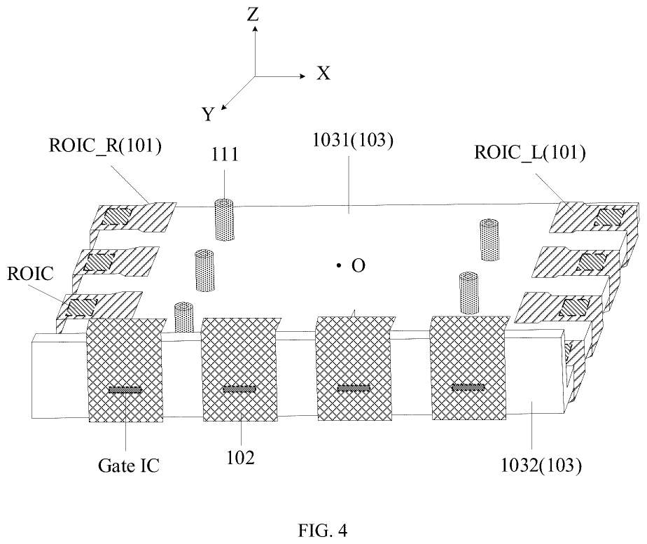

In some embodiments, in combination with FIG. 2 to FIG. 4, it can be seen that the above-mentioned detection apparatus provided in the embodiments of the present disclosure may also include a middle frame 103. Optionally, the middle frame 103 includes a bottom frame 1031 and a side frame 1032. The bottom frame 1031 is arranged on a side of the back surface S2 facing away from the detection surface S1 to effectively support the detection substrate 100. The side frame 1032 is fixed to one end of the bottom frame 1031 adjacent to the third side edge S5, and the side frame 1032 is arranged on a side of the bottom frame 1031 facing away from the back surface S2. In some embodiments, the side frame 1032 can raise the second circuit board 102 so that on the side where the back surface S2 is arranged, the second circuit board 102 is higher than the first circuit board 101 in the first direction Z. Exemplarily, the first circuit board 101 extends to the side of the bottom frame 1031 facing away from the back surface S2, and the second circuit board 102 extends to the surface of the side frame 1032 facing away from the back surface S2. Of course, in specific implementation, other methods may also be used to make the second circuit board 102 higher than the first circuit board 101 in the first direction Z on the side where the back surface S2 is arranged, and the present disclosure does not make specific limitations.

Continuing to refer to FIG. 2 to FIG. 4, it can be seen that the reading chip (ROIC) of the first circuit board 101 is arranged on the side of the bottom frame 1031 facing away from the back surface S2, and the gate driving chip (Gate IC) of the second circuit board 102 is arranged on the outer surface of the side frame 1032 facing away from the center of the detection substrate 100. The outer surface is arranged on the side where the third side edge S5 is arranged. Optionally, the gate driving chip (Gate IC) is in contact with the outer surface. In this way, the reading chip (ROIC) can be further away from the detection surface S1, avoiding the radiation effect on the reading chip (ROIC) caused by the large dose of x-rays received by the detection surface S1 or incident from the side of the detection surface S1.

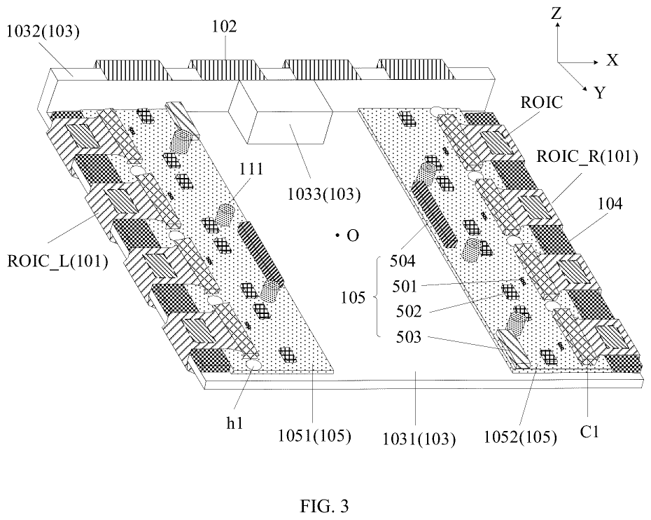

In some embodiments, in the above-mentioned detection apparatus provided in the embodiments of the present disclosure, as shown in FIG. 2 and FIG. 3, a heat-conducting structure 104 may also be included. The heat-conducting structure 104 is arranged between the first circuit board 101 and the bottom frame 1031, and is in contact with the reading chip (ROIC) and the surface of the bottom frame 1031 facing away from the back surface S2. The reading chip (ROIC) generates a lot of heat during operation. By setting a heat-conducting structure 104 that is in contact with the reading chip (ROIC) and the bottom frame 1031 at the same time, the heat of the reading chip (ROIC) can be transferred to the bottom frame 1031 through the heat-conducting structure 104, thereby dissipating the heat and ensuring the normal operation of the system. In some embodiments, the material of the heat-conducting structure 104 includes but is not limited to thermally conductive silicone.

Continuing to refer to FIG. 3, it can be seen that the heat-conducting structure 104 can be in the shape of a long strip, so that the heat of multiple reading chips (ROIC) on a single side (for example, the left side or the right side) can be transferred to the bottom frame 1031 through the same heat-conducting structure 104, and compared with the solution of only setting the heat-conducting structure 104 one by one at a single reading chip (ROIC), the area of the long strip heat-conducting structure 104 that contacts multiple reading chips (ROIC) at the same time is larger, so that the heat of the reading chip (ROIC) can not only be transferred to the bottom frame 1031 through the heat-conducting structure 104 overlapping with the reading chips (ROIC), but also can be transferred to the bottom frame 1031 through the heat-conducting structure 104 that does not overlap with the reading chips (ROIC), thereby dissipating the heat of the reading chip (ROIC) to the bottom frame 1031 more quickly, having a better cooling effect on the reading chip (ROIC), and ensuring that the temperature of the reading chip (ROIC) is normal.

In some embodiments, in the above-mentioned detection apparatus provided by the embodiment of the present disclosure, as shown in FIG. 2 to FIG. 4, the plurality of first circuit boards 101 may include a plurality of first sub-circuit boards ROIC_L and a plurality of second sub-circuit boards ROIC_R. The plurality of first sub-circuit boards ROIC_L extend from the side where the detection surface S1 is arranged through the first side edge S3 to the side of the bottom frame 1031 facing away from the back surface S2. The plurality of second sub-circuit boards ROIC_R extend from the side where the detection surface S1 is arranged through the second side edge S4 to the side of the bottom frame 1031 facing away from the back surface S2. The arrangement positions of the plurality of first sub-circuit boards ROIC_Land the arrangement positions of the plurality of second sub-circuit boards ROIC_R are symmetrical about the second direction Y, and the channel numbers of the plurality of first sub-circuit boards ROIC_L and the channel numbers of the plurality of second circuit boards ROIC_R are symmetrically arranged about the center O of the detection substrate 100, and the second direction Y is the vertical direction of the third side edge S5. In this arrangement, the plurality of first sub-circuit boards ROIC_L and the plurality of second sub-circuit boards ROIC_R can be used to realize bilateral driving of the detection substrate 100. Of course, in some embodiments, the entire first circuit board 101 may extend to the side of the back surface S2 through the first side edge S3 or the second side edge S4, and the entire first circuit board 101 may be used to realize unilateral driving of the detection substrate 100, which is not limited here.

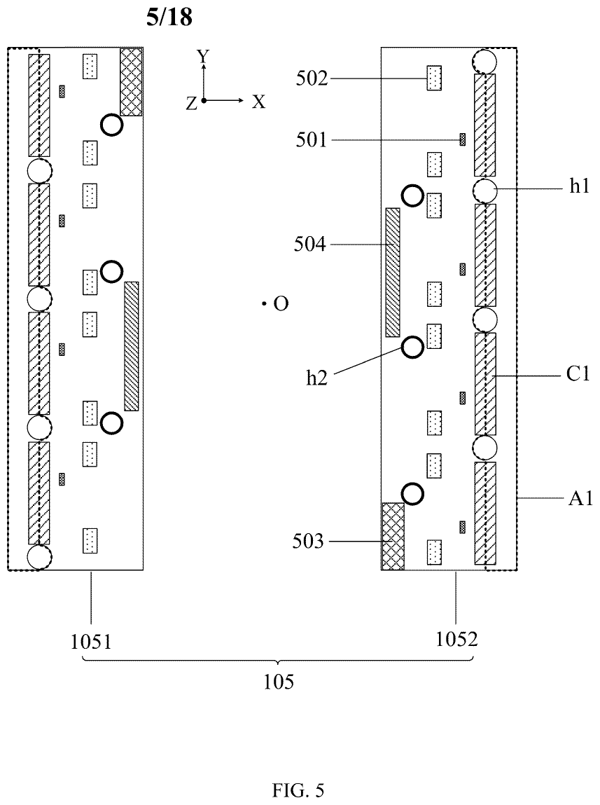

In some embodiments, in the above-mentioned detection apparatus provided by the embodiment of the present disclosure, as shown in FIG. 2, FIG. 3 and FIG. 5, two reading circuit boards 105 (for example, a first reading circuit board 1051 and a second reading circuit board 1052) arranged on the side of the bottom frame 1031 facing away from the back surface S2 may also be included. One reading circuit board 105 (for example, the first reading circuit board 1051) is connected to a plurality of first sub-circuit boards ROIC_L, and the other reading circuit board 105 (for example, the second reading circuit board 1052) is connected to a plurality of second sub-circuit boards ROIC_R, and the component structures of the two reading circuit boards 105 (for example, the first reading circuit board 1051 and the second reading circuit board 1052) are symmetrically arranged about the center O of the detection substrate 100. In this way, by using two reading circuit boards 105 (for example, the first reading circuit board 1051 and the second reading circuit board 1052) with the same component structure, the reading of electrical signals on the left and right sides can be realized, saving costs. At the same time, the design of the two reading circuit boards 105 (for example, the first reading circuit board 1051 and the second reading circuit board 1052) can be unified to reduce the workload during design and production. Further, the unified design can prevent mistakes and prevent incorrect installation. At the same time, corresponding space is reserved for the installation operation of the connecting piece (used to connect the reading circuit board 105 and the main control board 107).

In some embodiments, in the above-mentioned detection apparatus provided by the embodiment of the present disclosure, as shown in FIG. 3, FIG. 5 to FIG. 8, the reading circuit board 105 (for example, the first reading circuit board 1051 and the second reading circuit board 1052) includes at least one first through hole h1 disposed adjacent to the first circuit board 101. FIG. 3, FIG. 5 to FIG. 8 specifically show that the reading circuit board 105 (for example, the first reading circuit board 1051 and the second reading circuit board 1052) has four first through holes h1, and the first through holes h1 and the first connection port C1 (for realizing the electrical connection between the first circuit board 101 and the reading circuit board 105) are alternately disposed in the second direction Y. In some embodiments, the reading circuit board 105 (for example, the first reading circuit board 1051 and the second reading circuit board 1052) is fixedly connected to the bottom frame 1031 at at least one first through hole h1.

Since there are many boards in the entire driving system, and the ground signal is used as the reference signal of the entire driving system, integrity directly of the ground signal affects the image acquisition quality. In order to ensure the reliable connection of the ground network of each system, the present disclosure can use the middle frame 103 as the ground plane of the driving system. The first through hole h1 used to fix the reading circuit board 105 (such as the first reading circuit board 1051 and the second reading circuit board 1052) to the bottom frame 1031 can be designed as a conductive hole (such as a metallized fixing hole) to ensure that the reading circuit board 105 (such as the first reading circuit board 1051 and the second reading circuit board 1052) is connected to the ground network.

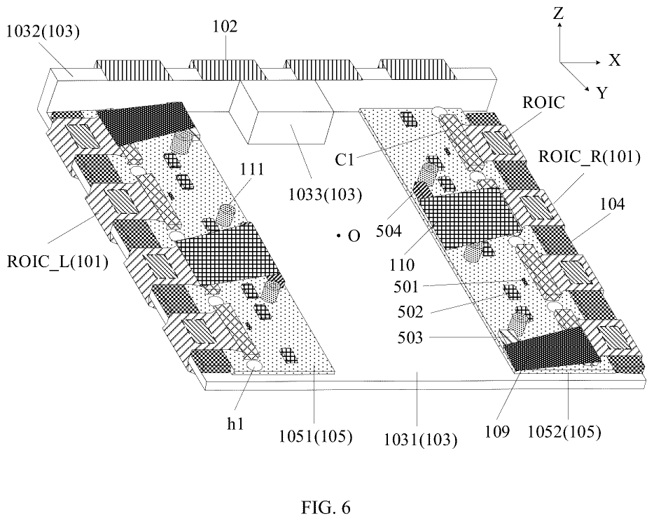

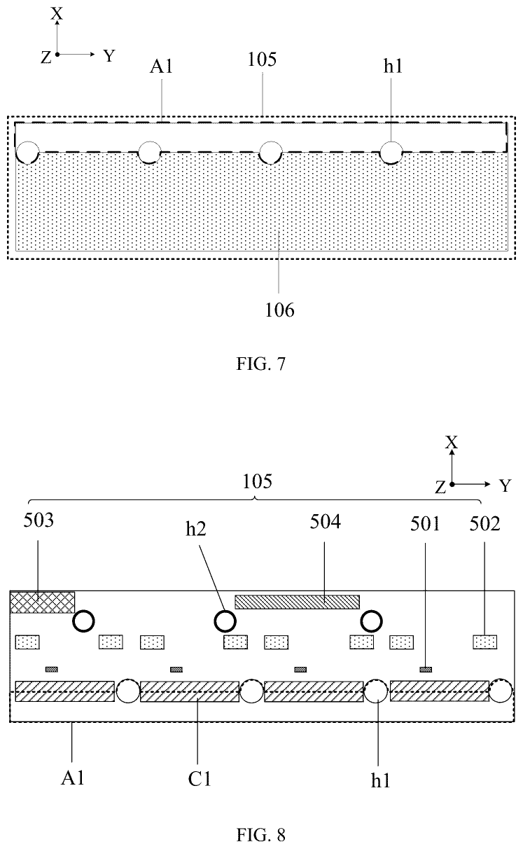

In some embodiments, in the above-mentioned detection apparatus provided by the embodiments of the present disclosure, as shown in FIG. 7 and FIG. 8, the reading circuit board 105 (for example, the first reading circuit board 1051 and the second reading circuit board 1052) may also include a first edge region A1 close to one side of at least one first through hole h1 and facing away from the center of the detection substrate 100 (i.e., close to the first side edge S3 or the second side edge S4). Specifically, the first reading circuit board 1051 has a first edge region A1 close to the first side edge S3, and the second reading circuit board 1052 has a first edge region A1 close to the second side edge S4. Optionally, the surface of the reading circuit board 105 (for example, the first reading circuit board 1051 and the second reading circuit board 1052) in contact with the bottom frame 1031 is conductively arranged in the first edge region A1 to ensure that the reading circuit board 105 (for example, the first reading circuit board 1051 and the second reading circuit board 1052) is fully in contact with the bottom frame 1031, so as to better connect to the ground network.

In some embodiments, the conductive property can be achieved by not coating the protective layer (e.g., green oil) on the surface of the reading circuit board 105 (e.g., the first reading circuit board 1051 and the second reading circuit board 1052) in contact with the bottom frame 1031 at the first edge region A1 and the first through hole h1. Optionally, in order to protect the reading circuit board 105 (e.g., the first reading circuit board 1051 and the second reading circuit board 1052) from corrosion caused by water, oxygen, etc., the present disclosure can coat the first protective layer 106 (e.g., green oil) on the surface of the reading circuit board 105 (e.g., the first reading circuit board 1051 and the second reading circuit board 1052) in contact with the bottom frame 1031, except for the first edge region A1 and the first through hole h1, as shown in FIG. 7.

In some embodiments, in the above-mentioned detection apparatus provided in the embodiment of the present disclosure, it can be seen from FIG. 3, FIG. 5, FIG. 6 and FIG. 8 that the reading circuit board 105 may also include at least one first electrostatic (ESD) protection circuit 501 disposed adjacent to the first circuit board 101 to prevent static electricity from interfering with the reading circuit board 105. Optionally, as shown in FIG. 3, FIG. 5, FIG. 6 and FIG. 8, the first electrostatic protection circuit 501 may be disposed on a side of the first connection port C1 close to the center O of the detection substrate 100, and the first electrostatic protection circuit 501 may be disposed adjacent to the first connection port C1, so that the first electrostatic protection circuit 501 is disposed closer to the first edge region A1 of the reading circuit board 105, thereby achieving a good protection effect against external static electricity (such as human body static electricity). Considering that the data signals collected by the reading circuit board 105 are mainly differential (LVDS) signals with a transmission rate of more than 100 MHz, the first electrostatic protection circuit 501 can select a diode with small parasitic capacitance and suitable for differential signal transmission. For example, the present disclosure adopts a differential (LVDS) signal-specific electrostatic protection diode array provided by Littlefuse, model SP3012-06UTG. The diode array has a 14-pin package, can protect 3 pairs of differential (LVDS) signals, and has a parasitic capacitance of 0.3 pF.

In some embodiments, in the above-mentioned detection apparatus provided in the embodiment of the present disclosure, as shown in FIG. 3, FIG. 5, FIG. 6 and FIG. 8, in order to ensure the power supply stability of the reading circuit board 105, the reading circuit board 105 can be set to further include at least one first filter circuit 502, and at least one first filter circuit 502 is arranged on a side of at least one first electrostatic protection circuit 501 close to the center O of the detection substrate 100. In other words, at least one first filter circuit 502 can be arranged on a side of at least one first electrostatic protection circuit 501 facing away from the first connection port C1. Continuing to refer to FIG. 3, FIG. 5, FIG. 6 and FIG. 8, it can be seen that the first filter circuit 502 can be staggered with the first electrostatic protection circuit 501 in the third direction X, and the first filter circuit 502 is arranged roughly side by side with the end of the first connection port C1 in the third direction X. The third direction X is the vertical direction of the first side edge S3. In some embodiments, the first filter circuit 502 includes a filter capacitor, for example, the specification of the filter capacitor is 47 μF\20V.

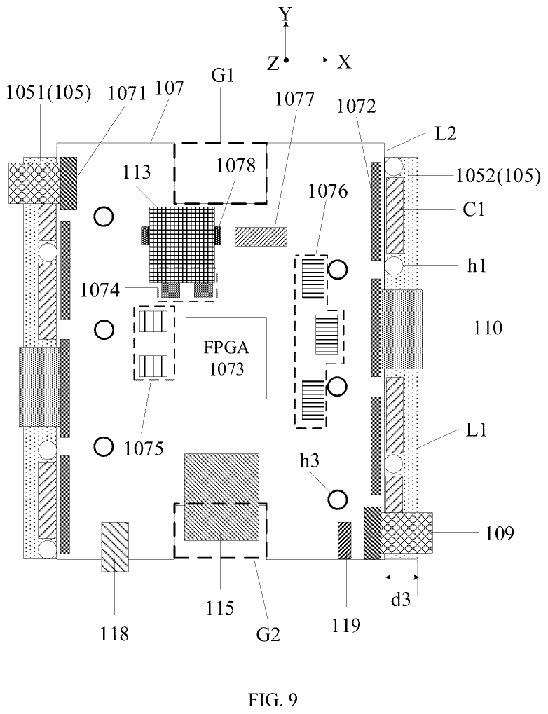

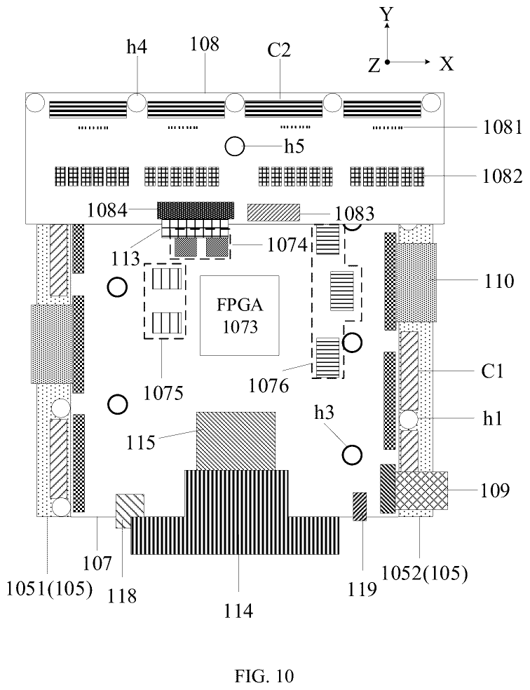

In some embodiments, in the above-mentioned detection apparatus provided in the embodiment of the present disclosure, as shown in FIG. 9 and FIG. 10, a main control board 107 and a gate drive circuit board 108 may also be included. The gate drive circuit board 108 is connected to the second circuit board 102, and the main control board 107 is arranged between the layer where the reading circuit board 105 is arranged and the layer where the gate drive circuit board 108 is arranged. In combination with the above content, it can be known that the reading circuit board 105 is arranged on the surface of the bottom frame 1031 facing away from the detection substrate 100. Therefore, in the present disclosure, the reading circuit board 105, the main control board 107 and the gate drive circuit board 108 are sequentially arranged on the side of the bottom frame 1031 facing away from the detection substrate 100. This way of designing different circuit boards in layers is conducive to the assembly between the circuit boards.

Continuing to refer to FIG. 9, it can be seen that in the above-mentioned detection apparatus provided by the embodiment of the present disclosure, the reading circuit board 105 includes a first boundary L1 facing away from the center O of the detection substrate 100 and extending along the second direction Y, and the main control board 107 includes a second boundary L2 facing away from the center O of the detection substrate 100 and extending along the second direction Y. The first boundary L1 is arranged on a side of the second boundary L2 facing away from the center O of the detection substrate 100, and there is a third distance d3 between the first boundary L1 and the second boundary L2. In other words, the reading circuit board 105 exceeds the main control board 107 by the third distance d3 in the third direction X, the second direction Y is the vertical direction of the third side edge S5, and the third direction X is the vertical direction of the first side edge S1, that is, the reading circuit board 105 has an edge region not covered by the main control board 107. Optionally, within the third distance d3 where the reading circuit board 105 exceeds the main control board 107, the first connection port C1 for connecting the first circuit board 101 and the reading circuit board 105 can be provided. By disposing the reading circuit board 105 beyond the main control board 107 in the third direction X, the first circuit board 101 with the reading chip (ROIC) can be installed more conveniently. Specifically, since it is necessary to press the piano cover of the first connection port C1 (such as a connector) on the reading circuit board 105 when fixing the first circuit board 101 on the reading circuit board 105, if the main control board 107 completely covers the reading circuit board 105, the main control board 107 must be removed when disassembling and installing the first circuit board 101, otherwise it cannot be operated, which will result in the entire driving system having to be removed when replacing the detection substrate 100. By reducing the size of the main control board 107, the installation and removal space of the first circuit board 101 can be reserved without removing the board.

Continuing to refer to FIG. 10, it can be seen that in the third direction X, the size of the gate drive circuit board 108 is larger than the size of the reading circuit board 105 and the size of the main control board 107. This is because the size of the entire driving system in the third direction X is consistent with the size of the detection substrate 100, and the size of the gate drive circuit board 108 in the third direction X is equal to the size of the detection substrate 100. The folding space needs to be reserved on both sides of the reading circuit board 105, so in the third direction X, its width is smaller than the width of the gate drive circuit board 108. The reading circuit board 105 and the main control board 107 are both fixed on the bottom frame 1031, so in the third direction X, the width of the main control board 107 is smaller than the width of the bottom frame 1031 (equivalent to the width of the detection substrate 100).

In some embodiments, in the above-mentioned detection apparatus provided in the embodiment of the present disclosure, as shown in FIG. 5, FIG. 6, FIG. 9 to FIG. 10, a first flat flexible cable (FFC) 109 may also be included. The reading circuit board 105 further includes a first power signal connector 503. The main control board 107 includes a second power signal connector 1071. The first power signal connector 503 is connected to the second power signal connector 1071 through the first flat flexible cable 109, so as to realize the independent power supply of the main control board 107 to the reading circuit board 105. In addition, the first flat flexible cable 109 can arbitrarily select the number and spacing of the wires, making the wiring more convenient, greatly reducing the volume of electronic products, reducing production costs, and improving production efficiency. In addition, since there is a bias (Vbias) power supply in the reading circuit board 105, the bias (Vbias) power supply is the reference power supply of the circuit in the detection substrate 100, which is generally −6V, and the data signal working voltage of the reading circuit board 105 is 2.5V. If the two are short-circuited, the reading circuit board 105 will be damaged. For safety reasons, the bias (Vbias) power supply can be separated as a sub-power supply of the main control board 107 and connected to the reading circuit board 105. Separating the bias (Vbias) power supply also has another advantage: after the bias (Vbias) power supply is separated, the remaining data signals are all differential (LVDS) data signals with the same electrical properties, so the first power signal connector 503 cooperates with any other first data signal connector 504 to drive the reading circuit board 105. In addition, by disposing the second power signal connector 1071 on the main control board 107 to independently power the reading circuit board 105, subsequent interface expansion is convenient, and the design cost and material cost required for expansion are reduced.

Continuing to refer to FIG. 5, FIG. 6, FIG. 9 and FIG. 10, it can be known that in the above-mentioned detection apparatus provided in the embodiment of the present disclosure, a first flexible circuit board 110 may also be included. The reading circuit board 105 may also include a first data signal connector 504. The main control board 107 may include a plurality of second data signal connectors 1072. The first data signal connector 504 may be connected to at least one second data signal connector 1072 through the first flexible circuit board 110. The number of the second data signal connectors 1072 may be greater than the number of the first data signal connectors 504 or the number of the first flexible circuit boards 110, so that the scalability of the driving system may be ensured. In addition, since the length of the first flexible circuit board 110 may be purchased according to demand, the driving system structure of the present disclosure has good scalability. When the size of the detection substrate 100 changes, the reading circuit board 105 may be placed as needed, and the first flexible circuit board 110 may be designed or purchased as a finished product according to a specific location.

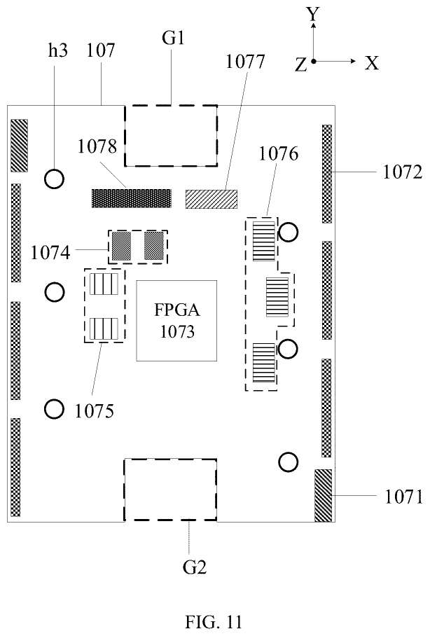

Optionally, as shown in FIG. 5, on the reading circuit board 105, the first power signal connector 503 and the first data signal connector 504 are arranged on a side of the first filter circuit 502 close to the center O of the detection substrate 100, and the first power signal connector 503 and the first data signal connector 504 can be arranged side by side in the second direction Y. As shown in FIG. 11, on the main control board 107, the second power signal connector 1071 and the second data signal connector 1072 are arranged at two edges of the main control board 107 facing away from the center O of the detection substrate 100 and extending along the second direction Y. The second power signal connector 1071 and the plurality of second data signal connectors 1072 at a single edge can also be arranged side by side in the second direction Y.

In some embodiments, as shown in FIG. 9 and FIG. 11, the present disclosure divides the interface connector between the main control board 107 and a reading circuit board 105 into four parts, including one second power signal connector 1071 and three second data signal connectors 1072. The signal definitions of the three second data signal connectors 1072 are completely consistent, which can ensure that the second power signal connector 1071 and any second data signal connector 1072 can drive a reading circuit board 105. The number of second data signal connectors 1072 used can be freely selected according to the size of the detection substrate 100. Since the number of first circuit boards 101 on a single side is 12 for the commonly used detection substrate of the largest size, and the present embodiment takes the number of first circuit boards 101 on a single side as 4 as an example, and combined with the size of the connector and comprehensive layout considerations, the main control board 107 of the present disclosure is designed with three second data signal connectors 1072 on a single side, and each second data signal connector 1072 can control the signals of the four first circuit boards 101 on the same side.

In some embodiments, the second data signal connector 1072 can be a small video connector (eDP). The eDP connector is a communication interface commonly used on computer display screens. It has a micro-packet structure, can realize the simultaneous transmission of a large amount of data, can ensure the reliable transmission of differential signals, and has a 4-lanes transmission rate of up to 21.6 Gbps. It is 26.3 mm wide and 1.1 mm high. It has a small size, which is conducive to the thinness of the product. Optionally, the small video connector (eDP) includes a shielding layer, and the shielding layer is grounded. Since the small video connector (eDP), the first flexible circuit board 109, and the first data signal connector 504 are conductive, it is equivalent to that the shielding layer of the small video connector (eDP) is conductive with the shielding layer of the first flexible circuit board 109. When the shielding layer of the small video connector (eDP) is grounded, the shielding layer of the first flexible circuit board 109 is also grounded, thereby reducing the interference of external signals on the differential signal transmitted by the first flexible circuit board 109 and increasing the anti-interference ability of the system.

Ordinary signal routing is a single-ended signal line, and the line spacing needs to be greater than 3 times the line width to reduce interference between signals. The cable impedance is generally 50 ohms. The differential design cable uses two cables to transmit one signal. The two cables are close together to reduce common-mode interference. At the same time, the two cables need to be designed to be equal in length, and the holes are changed at the same time. The differential line impedance is generally 100 ohms. It can transmit signals at a higher rate. Based on this, in some embodiments, the first flexible circuit board 109 may have multiple differential design cables to increase the signal transmission rate. Optionally, the differential design cables are isolated with ground to reduce electromagnetic interference between each other. In some embodiments, the first flexible circuit board 109 may also include a plurality of pins arranged side by side. Optionally, the outermost pins are grounded, and the remaining pins are connected to the differential design cables one by one, which can also reduce the interference of external electromagnetic signals on the differential signals on the differential design cables.

In some embodiments, in the above-mentioned detection apparatus provided by the embodiments of the present disclosure, as shown in FIG. 5 and FIG. 8 to FIG. 11, the reading circuit board 105 also includes at least one second through hole h2. Optionally, the second through hole h2 is arranged on a side of the first filter circuit 502 close to the center O of the detection substrate 100. The main control board 107 includes at least one third through hole h3 that is conductively connected to the at least one second through hole h2, for example, the third through hole h3 is conductively connected to the second through hole h2 one by one, and optionally, the third through hole h3 is arranged on a side of the row where the second power signal connector 1071 and the second data signal connector 1072 are arranged close to the center O of the detection substrate 100. The main control board 107 is fixedly connected to the bottom frame 1031 at at least one third through hole h3, and optionally, the main control board 107 is connected to the bottom frame 1031 at the third through hole h3 through a fixing column 111 and a screw. Since the middle frame 103 of the present disclosure can be used as the ground plane of the driving system, in some embodiments, the third through hole h3 can be designed as a conductive hole (such as a metallized fixing hole) to ensure that the main control board 107 is connected to the ground network.

In some embodiments, as shown in FIG. 11, the main control board 107 may also include an FPGA main control 1073, a DDR3 cache 1074, a FLASH storage 1075, a system power supply 1076, etc. The FPGA main control 1073 is the main control unit of the system, and its main functions include: ROIC data stream processing function, GATE IC signal driving function, power supply control function, synchronous exposure control, indicator light control function, and sensor control function. The DDR3 cache 1074 is a system cache, and the 8 ROIC signals received by the FPGA main control 1073 are first cached in the DDR3, and then transmitted after proofreading and framing. The FLASH storage 1075 is used to store the operating code of the system. The system power supply 1076 supplies power to the entire driving system and each connection port.

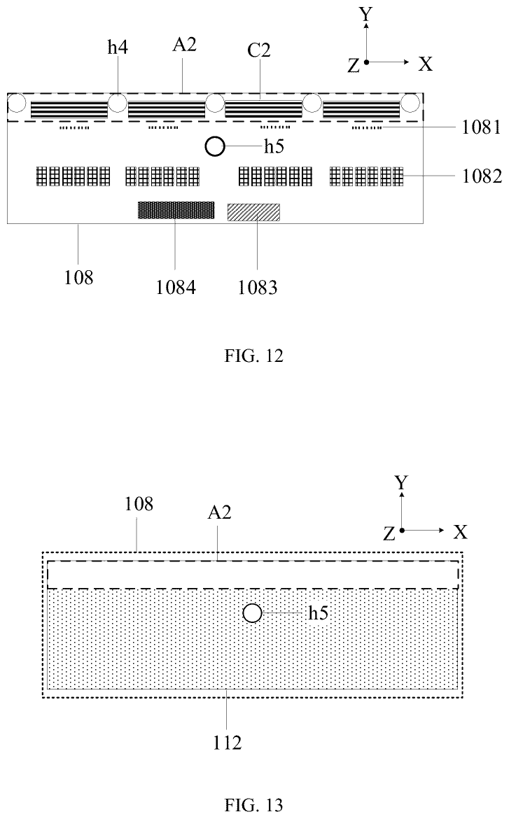

In some embodiments, in the above-mentioned detection apparatus provided in the embodiment of the present disclosure, as shown in FIG. 10 and FIG. 12, the gate drive circuit board 108 includes at least one fourth through hole h4, and the gate drive circuit board 108 is fixedly connected to the side frame 1032 at at least one fourth through hole h4. Optionally, the fourth through hole h4 and the second connection port C2 (used to realize the electrical connection between the second circuit board 102 and the gate drive circuit board 108) are alternately arranged in the third direction X. Since the middle frame 103 is the ground plane of the present disclosure, the fourth through hole h4 can be disposed as a conductive hole so that the gate drive circuit board 108 is connected to the ground network.

In some embodiments, as shown in FIGS. 12 and 13, the gate drive circuit board 108 may further include a second edge region A2 covering at least one fourth through hole h4. The surface of the gate drive circuit board 108 in contact with the side frame 1032 is conductively arranged in the second edge region A2, so that the gate drive circuit 108 can be fully in contact with the bottom frame 1031, thereby better connected to the ground network. In some embodiments, the conductive properties of the gate drive circuit board 108 can be achieved by not coating the protective layer (e.g., green oil) on the surface of the gate drive circuit board 108 in contact with the bottom frame 1031 at the first edge region A1 and the fourth through hole h4. Optionally, as shown in FIG. 13, in order to protect the gate drive circuit board 108 and avoid corrosion caused by water, oxygen, etc., the present disclosure can coat the second protective layer 112 (e.g., green oil) on the surface of the gate drive circuit board 108 in contact with the bottom frame 1031, except for the second edge region A2 and the fourth through hole h4, which does not need to maintain the conductive properties.

In some embodiments, in combination with FIG. 2, FIG. 3, FIG. 6 and FIG. 12, it can be seen that the middle frame 103 further includes a boss structure 1033. The boss structure 1033 is fixed to the side of the bottom frame 1031 facing away from the back surface S2, and the boss structure 1033 is fixedly connected to the local surface of the side frame 1032 close to the bottom frame 1031. Optionally, the gate drive circuit board 108 further includes at least one fifth through hole h5, and the gate drive circuit board 108 is fixedly connected to the boss structure 1033 at at least one fifth through hole h5 to improve the fixing strength of the gate drive circuit board 108. In addition, since the middle frame 103 is the ground plane of the present disclosure, the fifth through hole h5 can be set as a conductive hole so that the gate drive circuit board 108 is connected to the ground network. Optionally, in the surface where the gate drive circuit board 108 contacts the bottom frame 1031, the fifth through hole h5 is also not coated with a protective layer (such as green oil).

In some embodiments, in the above-mentioned detection apparatus provided in the embodiment of the present disclosure, as shown in FIG. 10 and FIG. 12, the gate drive circuit board 108 further includes at least one second electrostatic protection circuit 1081 to prevent static electricity from interfering with the gate drive circuit board 108. Optionally, as shown in FIG. 10 and FIG. 12, the second electrostatic protection circuit 1081 can be arranged on the side of the second connection port C2 (used to connect the second circuit board 102 with the gate drive circuit board 108) close to the center O of the detection substrate 100, and the second electrostatic protection circuit 1081 is arranged adjacent to the second connection port C2, so that the second electrostatic protection circuit 1081 is arranged closer to the second edge region A2 of the gate drive circuit board 108, thereby achieving a good protection effect against external static electricity (such as human body static electricity). Considering that the main signals of the gate drive circuit 108 are CPV (line-by-line scan clock), OE (TFT turn-on signal), and STV (initial signal), which have low rates and are all 3.3V TTL single-ended signals, the second electrostatic protection circuit 1081 can use a single-ended signal Littlefuse's dedicated electrostatic protection diode, model V3.5MLA0603N.

In some embodiments, in the above-mentioned detection apparatus provided in the embodiment of the present disclosure, as shown in FIG. 12, the gate drive circuit board 108 may further include at least one second filter circuit 1082, and the at least one second filter circuit 1082 is arranged on the side of the at least one second electrostatic protection circuit 1081 close to the center O of the detection substrate 100. The main source of the image noise of the detection substrate 100 is that the image output is a line-by-line scanning mode, and the output conversion of each line of data is different in time. If the power supply of the gate drive circuit board 108 is unstable, the signals collected at different times are also unstable, and the output graph will have lateral noise. The second filter circuit 1082 can ensure the power supply stability of the gate drive circuit board 108. Optionally, the second filter circuit 1082 includes a plurality of filter capacitors, for example, the filter capacitor specification is 47 μF\20V.

In some embodiments, in the above-mentioned detection apparatus provided in the embodiment of the present disclosure, as shown in FIG. 10, a second flat flexible cable (not shown) may also be included. The gate drive circuit board 108 also includes a third power signal connector 1083. The main control board 107 includes a fourth power signal connector 1077, and the third power signal connector 1083 is connected to the fourth power signal connector 1077 through the second flat flexible cable, thereby realizing the independent power supply of the gate drive circuit board 108 by the main control board 107. In addition, the second flat flexible cable can arbitrarily select the number and spacing of wires, making the connection more convenient, greatly reducing the volume of electronic products, reducing production costs, and improving production efficiency. In addition, by arranging the fourth power signal connector 1077 on the main control board 107 to independently power the gate drive circuit board 108, it is convenient to expand the subsequent interface and reduce the design cost and material cost required for the expansion.

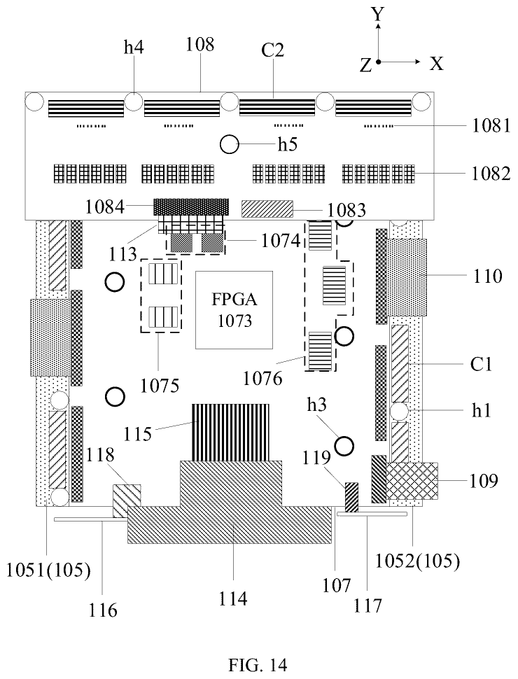

In some embodiments, in the above detection apparatus provided by the embodiment of the present disclosure, as shown in FIG. 10 and FIG. 14, a second flexible circuit board 113 may also be included. The gate circuit board 108 further includes a first scan signal connector 1084, the main control board 107 includes a second scan signal connector 1078, and the first scan signal connector 1084 is connected to the second scan signal connector 1078 through the second flexible circuit board 113. Since the length of the second flexible circuit board 113 can be purchased according to demand, the driving system structure of the present disclosure has good scalability. When the size of the detection substrate 100 changes, the gate drive circuit board 108 can be placed as needed, and the second flexible circuit board 113 can be designed or purchased as a finished product according to a specific position. Moreover, by arranging the second scan signal connector 1078 for controlling the gate drive circuit board 108 on the main control board 107, subsequent interface expansion can be facilitated, reducing the design cost and material cost required for expansion. In addition, since the power supply voltage of the gate driving chip (Gate IC) has a higher voltage signal of 16V/−8V, and the maximum tolerance voltage of the scanning signal is 3.6V, the signal of the gate drive circuit board 108 is divided into two parts in the present disclosure: a low-voltage signal and a power supply signal, which are transmitted through the second scan signal connector 1078 and the second power supply signal connector 1077 respectively, which can effectively prevent the second flexible circuit board 113 from causing a voltage short circuit due to misaligned installation and burning out the main control chip.

In some embodiments, in the above-mentioned detection apparatus provided in the embodiment of the present disclosure, it can be seen from FIG. 2 and FIG. 6 that the main control board 107 includes a first notch structure G1. The boss structure 1033 of the middle frame 103 can be accommodated in the first notch structure G1, so that the main control board 107 avoids the boss structure 1033, and ensures that the main control board 107 is stably fixed on the bottom frame 1031 of the middle frame 103. Optionally, referring to FIG. 11, the main control board 107 can also include a second notch structure G2, and the second notch structure G2 is arranged opposite to the first notch structure G1, that is, the second notch structure G2 is arranged adjacent to the end of the bottom frame 1031 facing away from the side frame 1032. As shown in FIG. 10 and FIG. 14, the driving system can also include a first adapter board 114, a part of the first adapter board 114 is embedded in the second notch structure G2, and the first adapter board 114 is connected to the main control board 107. Optionally, the first adapter board 114 is connected to the main control board 107 through a third flexible circuit board 115.

In some embodiments, the first adapter board 114 may include a USB (Universal Serial Bus) interface, a Gigabit Ethernet interface, a 10 Gigabit Ethernet interface, and a UART (Universal Asynchronous Receiver, Transmitter) interface, etc., to meet different application scenarios and application requirements of different transmission bandwidths, and improve the performance of the driving system. The main control board 107 can determine to use one of the interfaces of the first adapter board 114 to receive control instructions based on the bandwidth and application scenario. For example, for scenarios requiring high frame rate, large bandwidth, and dynamic acquisition, a 10 Gigabit Ethernet interface with an effective bandwidth of up to 1 GB/S can be used to receive control instructions; for another example, for scenarios requiring static acquisition, a Gigabit Ethernet interface with an effective bandwidth of up to 60 MB/S can be used to receive control instructions.

In some embodiments, in the above detection apparatus provided by the embodiment of the present disclosure, as shown in FIG. 14, it can also include an indicator light board 116 for indicating the working state of the main control board 107, and a power input board 117 for supplying power to the main control board 107. In some embodiments, the indicator light board 116 is connected to the main control board 107 through a fourth flexible circuit board 118, and the power input board 117 is connected to the main control board 107 through a fifth flexible circuit board 119. Optionally, the indicator light board 116, the power input board 117 and the first adapter board 114 are arranged on the same vertical plane of the detection surface S1, so that the distance between the indicator light board 116 and the detection substrate 100, the distance between the power input board 117 and the detection substrate 100, the distance between the first adapter board 114 and the detection substrate 100 are approximately the same, so as to facilitate the assembly of the indicator light board 116, the power input board 117, and the first adapter board 114 on the side where the fourth side edge S6 of the detection substrate 100 is arranged, and the fourth side edge S6 is arranged opposite to the third side edge S5 where the second circuit board 102 is arranged (as shown in FIG. 2). It should be noted that, due to the limitation of process conditions or the influence of other factors such as measurement, the “same vertical plane” disclosed in the present disclosure may have a position deviation of ±5%.

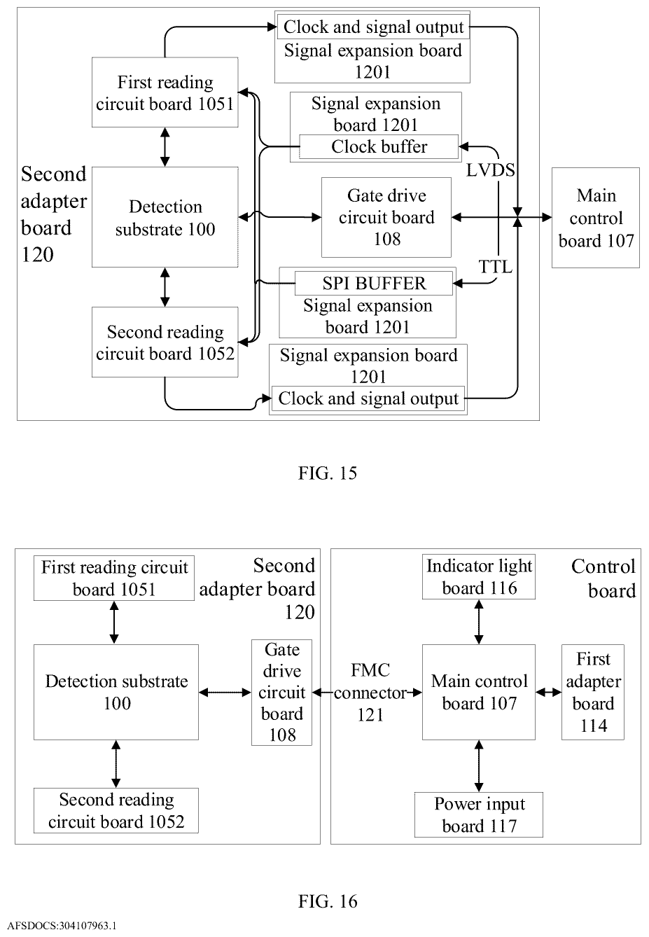

In some embodiments, in the above-mentioned detection apparatus provided in the embodiment of the present disclosure, as shown in FIG. 15, a second adapter board 120 may also be included. The second adapter board 120 may be integrated with a first reading circuit board 1051 connected to the first circuit board 101, a second reading circuit board 1052 and other reading circuit boards 105, and a plurality of signal expansion boards 1201 connected to the reading circuit board 105. The main control board 107 is connected to the reading circuit board 105 through the signal expansion board 1201. The first circuit board 101 has a reading chip ROIC. Since the number of signals of a single ROIC is large, but the repeatability is high, in view of this feature, the repeated signals can be merged and processed, so that the I/O port requirements of the main control board 107 can be reduced, and the number of signal lines can be reduced. The ROIC signal mainly includes three types: SPI control signal, clock input signal, and clock and data output signal. Among them, the SPI control signal is a TTL single-ended signal, and all ROIC control modes are consistent, which is a repeated signal. The clock input signal is an LVDS differential signal, and all ROIC control modes are consistent. The clock and data output signals are LVDS differential signals, with a total of 3 pairs of output signals. Therefore, the present disclosure uses the same signal expansion board 1201 (such as BUFFER chip) to perform a one-to-many design for the same ROIC signal. The SPI control signal uses the BUFFER chip with the model number N74AVCH16T245GR, which can expand one SPI control signal to 16 channels. The clock input signal and the clock and data output signal use the BUFFER chip with the model number ADCLK854BCPZ, which can expand one clock input signal and one clock and data output signal to 12 channels. In this way, only one set of SPI control signals and a pair of LVDS clocks need to be input to the second adapter board 120, and 8 ROICs can be driven.

In some embodiments, in the above-mentioned detection apparatus provided in the embodiment of the present disclosure, as shown in FIG. 16, a gold finger contact connector (FMC) 121 is also included. The second adapter board 120 includes a reading circuit board 105 (e.g., a first reading circuit board 1051 and a second reading circuit board 1052) connected to the first circuit board 101, and a gate drive circuit board 108 connected to the second circuit board 102. The main control board 107 is connected to the reading circuit board 105 and the gate drive circuit board 108 through the gold finger contact connector (FMC) 121. The gold finger contact connector (FMC) 121 can provide a standard mezzanine board (daughter card) size, connector and module interface for the FPGA on the basic board (carrier card). In this way, the I/O interface is separated from the FPGA, which not only simplifies the I/O interface module design, but also maximizes the reuse rate of the carrier card. The interface has the characteristics of large data throughput, supports a large number of I/O ports, and can support a large number of LVDS interfaces, and is particularly suitable for a large number of high-speed differential signal transmissions. To this end, the present disclosure arranges a gold finger contact connector (FMC) 121 between the second adapter board 120 and the main control board 107, which can connect all data and power signals of including but not limited to the reading circuit board 105 and the gate drive circuit board 108. In addition, due to the high data signal rate during ROIC transmission, in order to ensure the reliability of the signal, differential signal transmission is adopted, while the commonly used FPC is a parallel signal without a differential design. There will be impedance discontinuity during the transfer, resulting in signal reflection and affecting the signal quality. The interface of the gold finger contact connector (FMC) 121 has a corresponding impedance design, which can greatly improve the signal transmission quality.

In some embodiments, a board-to-board connector such as FMC is used between the main control board 107 and the second adapter board 120, which is not only compatible with scalability and signal integrity (i.e., high signal transmission quality), but also because the pin (PIN) density of the board-to-board connector is relatively large, the ground connection is more precise, which can save a lot of FPC and reduce the design complexity and assembly complexity of the system. However, there are two problems with the use of board-to-board connectors for docking. One is that the scalability of the board-to-board connector is weaker than that of the flexible circuit board connector. If it is necessary to drive a large-size detection substrate 100, it will be necessary to make a larger special-shaped PCB on the board-to-board connector to connect the main control board 107 and the second adapter board 120, which is not conducive to production; second, when the board-to-board connector is plugged in, the structural accuracy requirements are relatively high, and a large processing error is likely to cause the system to be unable to be installed, thereby increasing the difficulty of structural design and production costs. In view of this, the present disclosure preferably uses a flexible circuit board to realize the connection between the main control board 107 and the reading circuit board 105 and the gate drive circuit board 108 respectively.

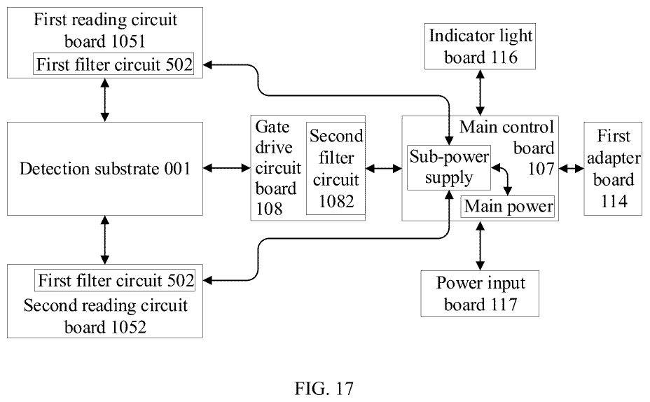

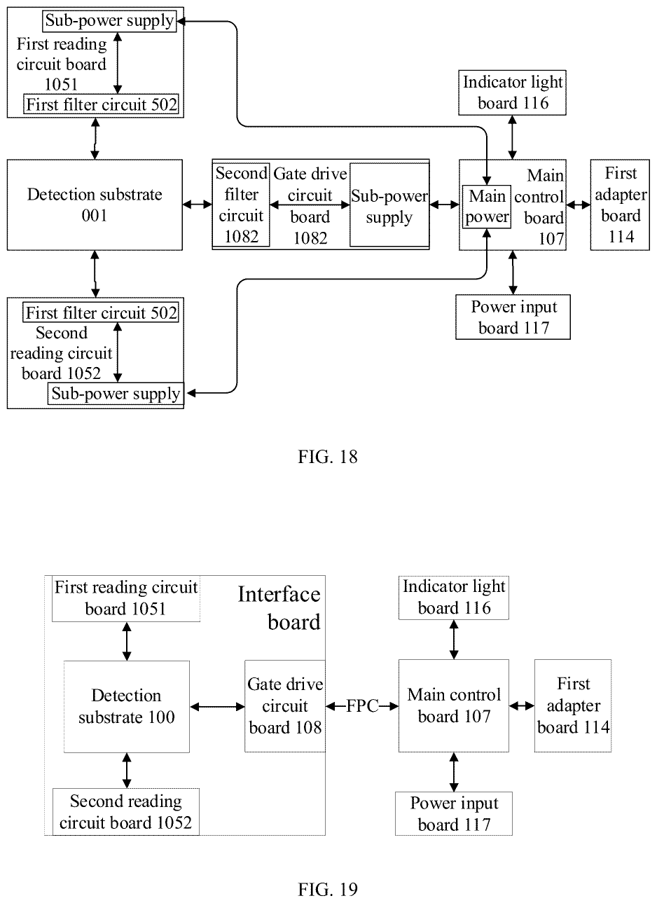

It should be noted that, as shown in FIG. 17, the present disclosure uses the sub-power supply on the main control board 107 to drive the reading circuit board 105 (e.g., the first reading circuit board 1051 and the second reading circuit board 1052) and the gate drive circuit board 108. However, in some embodiments, as shown in FIG. 18, in order to ensure the integrity of the power signal of the reading circuit board 105 (e.g., the first reading circuit board 1051 and the second reading circuit board 1052) and reduce the interference of the power signal during the transmission process, the sub-power supply can be integrated on the reading circuit board 105 (e.g., the first reading circuit board 1051 and the second reading circuit board 1052) and the gate drive circuit board 108, rather than on the main control board 107. However, since the reading circuit board 105 includes two boards, the first reading circuit board 1051 and the second reading circuit board 1052, there are two sets of sub-power supply systems for the reading circuit board 105, plus one set of sub-power supply systems for the gate drive circuit board 108, so a total of three sets of sub-power supply systems are required. Such a design will increase the additional cost compared with the driving system in which the sub-power supply is integrated on the main control board 107 as shown in FIG. 17.

Continuing to refer to FIG. 17, it can be seen that the first reading circuit board 1051, the second reading circuit board 1052 and the gate drive circuit board 108 of the present disclosure are three independent boards. In some embodiments, as shown in FIG. 19, the first reading circuit board 1051, the second reading circuit board 1052 and the gate drive circuit board 108 can be combined into a large board (for example, integrated on the same interface board), and the power supply system is designed on this interface board. Since the first reading circuit board 1051, the second reading circuit board 1052 and the gate drive circuit board 108 are on the same interface board, the ground reference is the same ground plane. Compared with the first reading circuit board 1051, the second reading circuit board 1052 and the gate drive circuit board 108 are three independent boards, this decentralized design has better ground consistency, more stable signals, and no additional cost is added. However, when the system drives a large-size detection substrate 100, the first reading circuit board 1051 and the second reading circuit board 1052 will be very large, and accordingly, the interface board integrated with the first reading circuit board 1051 and the second reading circuit board 1052 is also large, which is not conducive to production, and will also increase additional board costs.

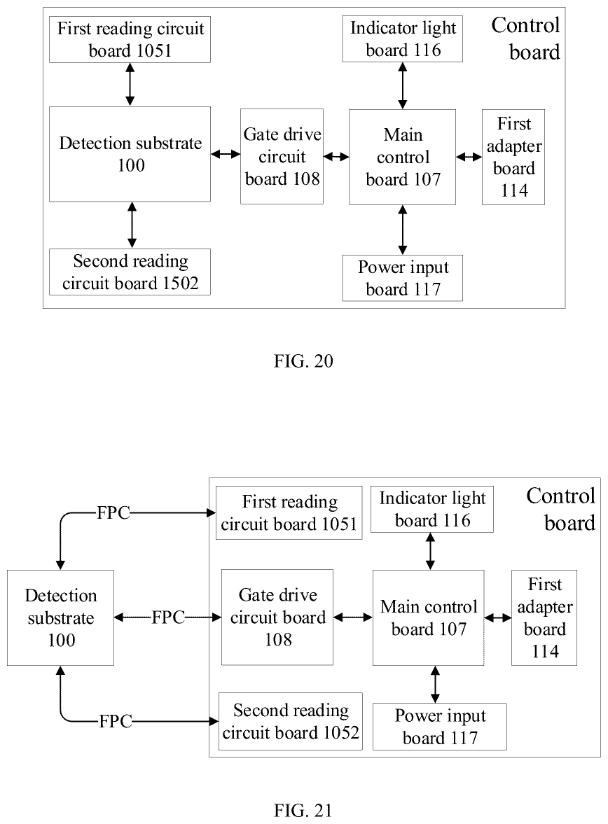

In some embodiments, considering that the first circuit board 101 and the second circuit board 102 mainly interfere with each other at the corners of the first side edge S2 and the third side edge S5, and at the corners of the second side edge S4 and the third side edge S5, in some embodiments, the first circuit board 101 or the second circuit board 102 at the two corners can be separated into small boards to solve the interference problem, and the entire driving system can be made into a large control board as shown in FIG. 20. In this way, the system will not have the phenomenon of poor ground signal contact, the signal integrity is the best, and the use of connectors such as flexible circuit boards can be reduced to reduce costs. However, the system does not have scalability, and when driving a large-size detection substrate 100, the control board will be very large, which is not conducive to production.

In some embodiments, the entire driving system can also be made into a smaller control board, as shown in FIG. 21, the first reading circuit board 1051, the second reading circuit board 1052, the main control board 107, the gate drive circuit board 108, the first adapter board 114, the indicator board 116, and the power input board 117 are integrated on the same control board. Compared with the above embodiment, the detection substrate 100 is arranged on one side of the bottom frame 1031, and the driving system (including stacking the reading circuit board 105, the main control board 107 and the gate drive circuit board 108 in sequence) is arranged on the opposite side of the bottom frame 1031. The layout of the detection substrate 100 and the driving system is more compact. In the scheme shown in FIG. 21, the detection substrate 100 is far away from the control board of the integrated driving system, and the first reading circuit board 1051, the second reading circuit board 1052, and the gate drive circuit board 108 can be connected to the detection substrate 100 using extended flexible circuit boards (FPCs) respectively. Optionally, in the scheme shown in FIG. 21, the electrical connection relationship between the main control board 107 and the first reading circuit board 1051, the second reading circuit board 1052, and the gate drive circuit board 108 can be the same as the electrical connection relationship in the scheme of arranging the detection substrate 100 on one side of the bottom frame 1031 and arranging the driving system on the opposite side of the bottom frame 1031, so as to ensure that the driving system can drive both large-sized detection substrates 100 and small-sized detection substrates 100, and when driving detection substrates 100 of different sizes, there is no need to design additional boards and cards, and no additional costs will be added. However, in the scheme shown in FIG. 21, a large number of extended FPCs are used, signal processing cannot be performed, and signal integrity cannot be guaranteed. At the same time, the difficulty of system wiring will be increased. When driving a large-sized detection substrate 100, the entire driving system will look messy.

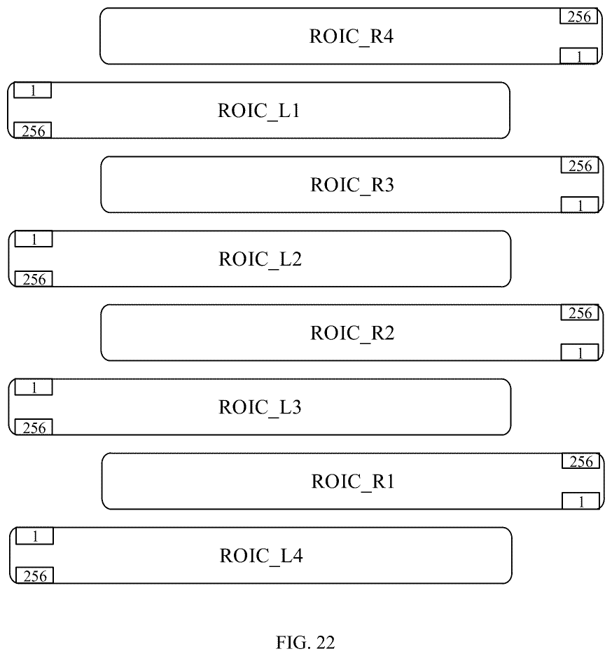

In some embodiments, the first sub-circuit boards ROIC_L and the second sub-circuit boards ROIC_R with the read chip (ROIC) in the present disclosure are symmetrically arranged, and the channel numbers of the first sub-circuit boards ROIC_L and the channel numbers of the second sub-circuit boards ROIC_R are also symmetrical. The data signals of each first sub-circuit board ROIC_L and the second sub-circuit board ROIC_R are always output sequentially from the first channel to the last channel. Taking each read chip ROIC having 256 channels (channel 1 to channel 256) as an example, in FIG. 22, ROIC_L1, ROIC_L2, ROIC_L3, and ROIC_L4 represent four first sub-circuit boards ROIC_L, and ROIC_R1, ROIC_R2, ROIC_R3, and ROIC_R4 represent four second sub-circuit boards ROIC_R. As can be seen from FIG. 22, the actual arrangement order of one frame of graphics is (ROIC_R4_256)~(ROIC_R4_1)~(ROIC_L1_1)~(ROIC_L1_256)~(ROIC_R3_256)~(ROIC_R3_1)~(ROIC_L2_1)~(ROIC_L2_256)~(ROIC_R2_256)~(ROIC_R2_1)~(ROIC_L3_1)~(ROIC_L3_256)~(ROIC_R1_256)~(ROIC_R1_1)~(ROIC_L4_1)~(ROIC_L4_256), so when actually assembling the graphics, it is necessary to flip the data of the second sub-circuit board ROIC_R and sort them according to the actual order.

Based on this, an embodiment of the present disclosure provides a driving method for a detection apparatus. Optionally, the detection substrate includes a plurality of data lines arranged in sequence, the plurality of first circuit boards include at least one first sub-circuit board connected to the odd-numbered data lines at one end of the data lines, and at least one second sub-circuit board connected to the even-numbered data lines at the other end of the data lines, and the at least one first sub-circuit board and the at least one second sub-circuit board are symmetrically arranged about the center of the detection substrate.

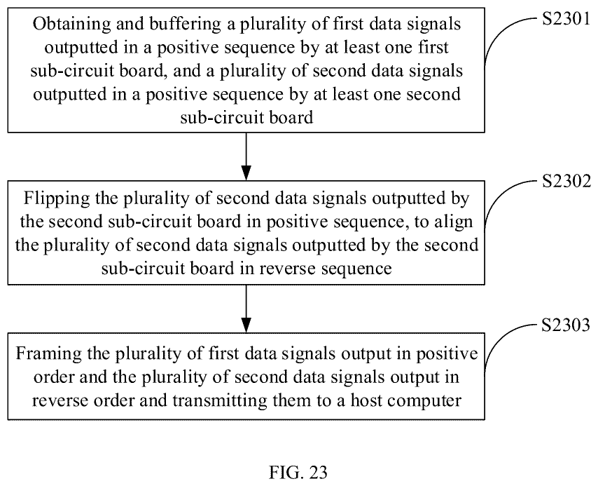

The driving method may include the steps shown in FIG. 23:
S2301, acquiring and buffering a plurality of first data signals outputted in a positive sequence by at least one first sub-circuit board, and a plurality of second data signals outputted in a positive sequence by at least one second sub-circuit board;
S2302, flipping the plurality of second data signals outputted by the second sub-circuit board in positive sequence, to align the plurality of second data signals outputted by the second sub-circuit board in reverse sequence;
S2303, framing the plurality of first data signals output in positive order and the plurality of second data signals output in reverse order and transmitting them to a host computer.

Although the preferred embodiments of the present disclosure have been described, those skilled in the art may make additional changes and modifications to these embodiments once they have learned the basic creative concept. Therefore, the appended claims are intended to be interpreted as including the preferred embodiments and all changes and modifications falling within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalents, the present disclosure is also intended to include these modifications and variations.

1. A detection apparatus, comprising:
a detection substrate comprising:
a detection surface and a back surface arranged opposite to each other, and
a first side edge, a second side edge, and a third side edge each connects the detection surface and the back surface,
wherein the first side edge is arranged opposite to the second side edge, and the third side edge connects the first side edge and the second side edge; and
a driving system comprising:
a plurality of first circuit boards, wherein the plurality of first circuit boards extend from a side where the detection surface is arranged to a side where the back surface is arranged, through at least one of the first side edge and the second side edge; a farthest distance between the first circuit boards on the side where the back surface is arranged and the back surface, in a first direction is a first distance, and the first direction is a direction perpendicular to the detection surface;
a plurality of second circuit boards, wherein the plurality of second circuit boards extend from the side where the detection surface is arranged to the side where the back surface is arranged through the third side edge; a farthest distance between the second circuit boards on the side where the back surface is arranged and the back surface, in the first direction is a second distance, and the second distance is unequal to the first distance.

2. The detection apparatus according to claim 1, wherein the first circuit board comprises a reading chip, the second circuit board comprises a gate driving chip, and the second distance is greater than the first distance.

3. The detection apparatus according to claim 2, further comprising a middle frame, wherein the middle frame comprises a bottom frame and a side frame, the bottom frame is arranged on a side of the back surface facing away from the detection surface, the side frame is fixed to an end of the bottom frame adjacent to the third side edge, and the side frame is arranged on a side of the bottom frame facing away from the back surface;
wherein the first circuit boards extends to the side of the bottom frame facing away from the back surface, and the second circuit boards extend to a surface of the side frame facing away from the back surface.

4. The detection apparatus according to claim 3, wherein the reading chip is arranged on the side of the bottom frame facing away from the back surface, and the gate driving chip is arranged on a side surface of the side frame arranged on a side where the third side edge is arranged; and/or
the plurality of first circuit boards comprise a plurality of first sub-circuit boards and a plurality of second sub-circuit boards, wherein the plurality of first sub-circuit boards extend from the side where the detection surface is arranged to the side of the bottom frame facing away from the back surface through the first side edge, and the plurality of second sub-circuit boards extend from the side where the detection surface is arranged to the side of the bottom frame facing away from the back surface through the second side edge; and an arrangement position of the plurality of first sub-circuit boards and an arrangement position of the plurality of second sub-circuit boards are symmetrical about a second direction, and the second direction is a direction perpendicular to the third side edge.

5. (canceled)

6. The detection apparatus according to claim 4, wherein the driving system further comprises two reading circuit boards arranged on the side of the bottom frame facing away from the back surface, wherein one of the two reading circuit boards is connected to the plurality of first sub-circuit boards, and the other one of the two reading circuit boards is connected to the plurality of second sub-circuit boards, and component structures of the two reading circuit boards are symmetrically arranged about a center of the detection substrate; and/or
the reading circuit board further comprises at least one first electrostatic protection circuit, the at least one first electrostatic protection circuit is arranged on a side of a first connection port close to the center of the detection substrate, and the first connection port connects the first circuit board with the reading circuit board; and/or
the driving system further comprises a gate drive circuit board and a main control board, wherein the gate drive circuit board is connected to the second circuit board, and the main control board is arranged between a layer where the reading circuit board is arranged and a layer where the gate drive circuit board is arranged.

7. The detection apparatus according to claim 6, wherein the reading circuit board comprises at least one first through hole, the reading circuit board is fixedly connected to the bottom frame at the at least one first through hole, and the at least one first through hole is a conductive hole.

8. The detection apparatus according to claim 7, wherein the reading circuit board further comprises a first edge region arranged on a side of the at least one first through hole facing away from the center of the detection substrate, and a surface of the reading circuit board in contact with the bottom frame is conductively arranged in the first edge region.

9. (canceled)

10. The detection apparatus according to claim 6, wherein the reading circuit board further comprises at least one first filtering circuit, and the at least one first filtering circuit is arranged on a side of the at least one first electrostatic protection circuit close to the center of the detection substrate.

11. (canceled)

12. The detection apparatus according to claim 6, wherein the reading circuit board comprises a first boundary facing away from the center of the detection substrate and extending along the second direction, and the main control board comprises a second boundary facing away from the center of the detection substrate and extending along the second direction, wherein the first boundary is arranged on a side of the second boundary facing away from the center of the detection substrate, and a third distance is provided between the first boundary and the second boundary; and/or
the driving system further comprises a first flat flexible cable, the reading circuit board further comprises a first power signal connector, the main control board comprises a second power signal connector, and the first power signal connector is connected to the second power signal connector through the first flat flexible cable; and/or
the driving system further comprises a first flexible circuit board, the reading circuit board further comprises a first data signal connector, the main control board comprises a plurality of second data signal connectors, the first data signal connector is connected to at least one of the second data signal connectors through the first flexible circuit board, and a quantity of the second data signal connectors is greater than a quantity of the first data signal connector or a quantity of the first flexible circuit board; and/or
the reading circuit board further comprises at least one second through hole, the main control board comprises at least one third through hole arranged to be conductively connected to the at least one second through hole, the main control board is fixedly connected to the bottom frame at the at least one third through hole, and the at least one third through hole is a conductive hole.

13. (canceled)

14. (canceled)

15. The detection apparatus according to claim 12, wherein the second data signal connector is a small video connector, the small video connector comprises a shielding layer, and the shielding layer is grounded; and/or
the first flexible circuit board comprises a plurality of pins arranged side by side, and a plurality of differential design cables, wherein an outermost pin of the plurality of pins are grounded, and remaining pins of the plurality of pins are connected to the differential design cables.

16. (canceled)

17. (canceled)

18. The detection apparatus according to claim 4, further comprising a heat-conducting structure, wherein the heat-conducting structure is arranged between the first circuit board and the bottom frame and is arranged in contact with the reading chip and a surface of the bottom frame facing away from the back surface; and/or
the driving system further comprises a gate drive circuit board, and the gate drive circuit board is connected to the second circuit board; the gate drive circuit board comprises at least one fourth through hole, and the gate drive circuit board is fixedly connected to the side frame at the at least one fourth through hole, and the at least one fourth through hole is a conductive hole; and/or
the middle frame further comprises a boss structure, the boss structure is fixed to the side of the bottom frame facing away from the back surface, and the boss structure is fixedly connected to a part of a surface of the side frame close to the bottom frame;
wherein the gate drive circuit board further comprises at least one fifth through hole, the gate drive circuit board is fixedly connected to the boss structure at the at least one fifth through hole, and the at least one fifth through hole is a conductive hole.

19. (canceled)

20. The detection apparatus according to claim 18, wherein the gate drive circuit board further comprises a second edge region covering the at least one fourth through hole, and a surface of the gate drive circuit board in contact with the side frame is conductively arranged in the second edge region.

21. The detection apparatus according to claim 20, wherein the gate drive circuit board further comprises at least one second electrostatic protection circuit, and the at least one second electrostatic protection circuit is arranged on a side of a second connection port close to the center of the detection substrate, and the second connection port connects the second circuit board with the gate drive circuit board.

22. The detection apparatus according to claim 21, wherein the gate drive circuit board further comprises at least one second filter circuit, and the at least one second filter circuit is arranged on a side of the at least one second electrostatic protection circuit close to the center of the detection substrate.

23. (canceled)

24. The detection apparatus according to claim 18, wherein the driving system further comprises a main control board arranged on a side of the gate drive circuit board facing the bottom frame, the main control board comprises a first notch structure, and the boss structure is accommodated in the first notch structure.

25. The detection apparatus according to claim 24, wherein the driving system further comprises a second flat flexible cable, the gate drive circuit board further comprises a third power signal connector, the main control board comprises a fourth power signal connector, and the third power signal connector is connected to the fourth power signal connector through the second flat flexible cable; and/or
the driving system further comprises a second flexible circuit board, the gate circuit board further comprises a first scan signal connector, the main control board comprises a second scan signal connector, and the first scan signal connector is connected to the second scan signal connector through the second flexible circuit board; and/or
the main control board further comprises a second notch structure, and the second notch structure is arranged opposite to the first notch structure;
wherein the detection apparatus further comprises a first adapter board, a part of the first adapter board is embedded in the second notch structure, and the first adapter board is connected to the main control board.

26. (canceled)

27. (canceled)

28. The detection apparatus according to claim 25, wherein the driving system further comprises an indicator light board and a power input board, and the indicator light board, the power input board and the first adapter board are arranged on a same vertical plane of the detection surface.

29. The detection apparatus according to claim 1, wherein the driving system further comprises a main control board and a second adapter board, wherein the second adapter board comprises a reading circuit board connected to the first circuit board, and a plurality types of signal expansion boards connected to the reading circuit board, and the main control board is connected to the reading circuit board through the signal expansion board.

30. The detection apparatus according to claim 1, wherein the driving system further comprises a main control board, a second adapter board and a gold finger contact connector, wherein the second adapter board comprises a reading circuit board connected to the first circuit board, and a gate drive circuit board connected to the second circuit board, and the main control board is connected to the reading circuit board and the gate drive circuit board through the gold finger contact connector.

31. A driving method of the detection apparatus according to claim 1, wherein the detection substrate comprises a plurality of data lines arranged in sequence, the plurality of first circuit boards comprise at least one first sub-circuit board connected to odd-numbered data lines at one end of the data lines, and at least one second sub-circuit board connected to even-numbered data lines at the other end of the data lines, the at least one first sub-circuit board and the at least one second sub-circuit board are symmetrically arranged about a center of the detection substrate;
wherein the driving method comprises:
obtaining and caching a plurality of first data signals output in positive sequence by the at least one first sub-circuit board and a plurality of second data signals outputted in positive sequence by the at least one second sub-circuit board;
flipping the plurality of second data signals output in positive sequence by the second sub-circuit board, to align the plurality of second data signals outputted by the second sub-circuit board in reverse sequence; and
framing and transmitting the plurality of first data signals output in positive sequence and the plurality of second data signals aligned in reverse sequence to a host computer.
